(19) United States
(12) Patent Application Publication
(10) Pub. No.: US 2024/0296883 A1
(43) Pub. Date: Sep. 5, 2024

(54) OPERATION SCHEME FOR FOUR TRANSISTOR STATIC RANDOM ACCESS MEMORY

(71) Applicant: FlashSilicon Incorporation, Diamond Bar, CA (US)

(72) Inventor: LEE WANG, Diamond Bar, CA (US)

(21) Appl. No.: 18/418,060

(22) Filed: Jan. 19, 2024

(30) Foreign Application Priority Data
Mar. 1, 2023 (CN) 2023101819122

(51) Int. Cl. G11C 11/419; G11C 11/412; G11C 11/418

(52) U.S. Cl. CPC G11C 11/419; G11C 11/412; G11C 11/418

(57) ABSTRACT

A memory device is disclosed, comprising a 4T-SRAM cell and a read circuit. The 4T-SRAM cell comprising two P-type MOSFET devices for a data bit storage and two N-type MOSFET for accessing switches has benefits of less numbers of MOSFET devices for smaller cell size and low leakage current than the conventional 6T-SRAM cell. The read circuit comprises a latch and a discharge device. The latch with two output nodes is coupled between a supply voltage rail and a ground voltage rail. The discharge device is coupled to the two output nodes, a bit line pair and the ground voltage rail. Since one of two storage nodes for the 4T-SRAM cell is floating, the stored data in the 4T-SRAM cell is vulnerable for conventional read operations. The read circuit of the invention resolves the vulnerability issue of the 4T-SRAM cell.

### BACKGROUND OF THE INVENTION

### Field of the Invention

This invention relates to four transistor (4T) Static Random Access Memory (SRAM) and the methods of operating the same. The 4T-SRAM cell comprising two p-type Metal Oxide Semiconductor Field Effect Transistor (MOSFET) devices (201, 202 in FIG. 2) for data storage and two n-type MOSFET devices (203, 204 in FIG. 2) for access switches are configured to form memory arrays. In particular, a read circuit and a write circuit designed for operating the 4T-SRAM cell are disclosed.

### Description of the Related Art

Semiconductor memories have been broadly applied to electronic systems. Electronic systems require semiconductor memories for storing instructions and data from the basic functions of controls to the complex computing data processes. Semiconductor memories can be catalogued as volatile memories and non-volatile memories. The volatile memories including Static Random Access Memory (SRAM) and Dynamic Random Access Memory (DRAM) lose their stored data after the memory's powers off while the non-volatile memories such as Read Only Memory (ROM), Electrical Erasable Programmable Read Only Memory (EEPROM) and flash still keep their stored data even without the memory power.

Since computer processors run at very high frequency clock speeds (MHz˜tens of GHz) the access time for reading data and altering data in memory have to be compatible with the computing speeds of computer processors. The volatile SRAM and DRAM are the memory of choices for computer processors due to their fast random memory access time for read/write operations. Meanwhile, a DRAM cell consisting of one MOSFET device for the access switch and one capacitor for data storage can be fabricated with DRAM process technology to a very high density with very low fabrication cost per-bit-storage. While the conventional 6T (six MOSFET devices) SRAM cell 100 consisting of six MOSFET devices: two N-type MOSFET devices (103 and 104) for data access switches, and two P-type and two N-type MOSFET devices (101,102,105 and 106) for data storage shown in FIG. 1, is fabricated with the CMOS (Complementary Metal Oxide Semiconductor) process technology, which is the same fabrication process technology as for digital processor circuits. However, the sizes of the conventional 6T SRAM cells occupy large silicon area leading to very high fabrication cost per-bit-storage. Therefore, it is very desirable to reduce the sizes of SRAM cells for increasing the memory density and lowering the fabrication cost per-bit-storage. On the other hand, for a bit of memory storage, the sizes of conventional 6T SRAM cell 100 in FIG. 1 can be reduced to the sizes of 4T (four MOSFET devices) SRAM cell 200 in FIG. 2 usually by 25%˜35% for a higher SRAM density and lower fabrication cost per-bit-storage.

Besides the benefit of smaller SRAM cell size, the 4T-SRAM cell 200 has less retention leakage current compared with the conventional 6T-SRAM cell 100. According to the 4T-SRAM cell schematic in FIG. 2 and the 6T SRAM cell schematic in FIG. 1, the data storage circuit 30L for the 4T SRAM cell 200 consisting of two cross-connected P-type MOSFET devices 201 and 202 in FIG. 3A does not have any device channel diffusion leakage current from the high voltage rail V_{DD} to the ground voltage (i.e., no low voltage nodes V_{SS} 246/245 connected to the ground voltage) for a bit of data storage, while the data storage circuit 30R for 6T SRAM cell 100 consisting of two cross-connected inverters 303 and 304 in FIG. 3B has PFET device channel diffusion leakage currents 35 and NFET device channel diffusion leakage currents 34 at the node 31 and 32 or vice versa from the high voltage rail V_{DD} to the ground voltage node V_{SS} for a bit of data storage. In general, the MOSFET device channel diffusion leakage currents are around tens of pA to 1 nA depending on MOSFET devices' designs and applied high voltage V_{DD}. The total standby leakage current for the conventional 6T SRAM arrays is (the number of SRAM cells)×(PFET device channel diffusion leakage current 35+NFET device channel diffusion leakage current 34). While 4T-SRAM has only N-drain/P-substrate (access NFET transistor 203/204) and P-drain/N-well (storage node) junction leakage currents, which are usually several orders of magnitude smaller than the MOSFET device channel diffusion leakage currents.

In one aspect of this invention, since the 4T-SRAM cell 200 does not have the low voltage node V_{SS} connected to the ground voltage as the conventional 6T-SRAM cell for being always biased with the ground voltage in one of the storage nodes, a write circuit 410 for 4T-SRAM cell 200 is designed to have the capability to initially set the voltage potentials of the cell's storage nodes 246/245 simultaneously to the high voltage V_{DD} and the ground voltage V_{SS}.

In one aspect of this invention, since the 4T-SRAM cell 200 does not have the low voltage node V_{SS} connected to the ground voltage as the conventional 6T-SRAM for being always biased with the ground voltage in one of the storage nodes, one floating storage node 245/246 of the 4T-SRAM cell 200 is required to restore to the ground voltage in read process for retaining the original stored datum. The read circuit 510 is designed to have the capability to restore the ground voltage for the floating storage node of the selected 4T-SRAM cell in read process.

In one aspect of this invention, since for the 4T-SRAM cell 200 the voltage potential of the floating storage node is below the high voltage potential V_{DD} of the other storage node, a read circuit 510 is designed to detect the asymmetrical voltage difference (V_{DD}-V_{floating}) between two storage nodes of the selected 4T-SRAM cell 200 such that the full digital voltage signals, the high voltage V_{DD} and the ground voltage V_{SS}, can be obtained for the output signals, where V_{floating} is the voltage potential of the floating storage node for the 4T-SRAM cell 200 during the data retention period as shown in FIG. 6. The floating storage node voltage potential V_{floating} is a voltage potential below the supply voltage V_{DD} and above the ground voltage. The steady-state floating storage node voltage potential for a 4T-SRAM cell (for example, see the curve 605 in FIG. 6) can be obtained for the detailed balanced leakage currents between the PFET device 201/202 channel diffusion current (V_{DD} to the steady V_{floating}) with the reversed P-drain/Nwell junction leakage current (V_{DD} to the steady V_{floating}) and the reversed N-drain/P-substrate junction leakage current of the access NFET device 203/204 (the steady V_{floating} to substrate). In general, the higher reversed N-drain/P-substrate junction of the access NFET device 203/204, the lower steady floating storage node voltage potential toward the ground voltage can be obtained.

In one aspect of this invention, the 4T-SRAM cell 200 does not have the low voltage node V_{SS} connected to the ground voltage as the conventional 6T-SRAM for being always biased with the ground voltage in one storage node, the read circuit 510 is designed to prevent the false reading caused by the residual charges on the bitlines/complementary bitlines in the 4T-SRAM array from altering the floating storage node voltage potential of the selected 4T-SRAM cell 200 for flipping the original stored data value to the false opposite data value.

### SUMMARY OF THE INVENTION

FIG. 4 shows a schematic diagram of a memory device 400 according to an embodiment of the invention. In FIG. 4, a memory device 400 includes the 4T-SRAM cell 200 and a write circuit 410. The write circuit 410 comprises a cross-connected pair of PFET devices 413 and 414, two NFET 415 and 416, a write-driver-enabled PFET device 411 and a write-driver-enabled NFET device 412. The gates of FET devices 411 and 412 are applied with a write-driver-enable voltage signal “WrDE” at node 431, for connecting the write circuit 410 to the high voltage rail V_{DD} and the ground voltage, respectively during data writing time period. The voltage signal DI, either a supply voltage V_{DD} for the datum “1” or the ground voltage for datum “0” at node 432, is inputted for the data to be stored in the 4T-SRAM cell 200. For writing a datum “1” into the memory cell 200 with the voltage V_{DD} to turn on the word-line W (gates of access NFET devices 203 and 204 in 4T-SRAM cell 200) at node 433, the NFET devices 415 and 416 are turned respectively “on” and “off” for the inputted voltage signal V_{DD} at node 432. The node 45 for the complementary bitline B̅L̅ 422 with loading capacitance 442 C_{BL} are connected through NFET device 412 to the ground voltage, while the node 46 for bitline BL 421 with loading capacitance C_{BL} 441 is charged to V_{DD} through PFET device 414 with NFET device 416 off. Meanwhile the ground voltage at node 45 is passed through the complementary bitline B̅L̅ 422 and the access transistor 203 to turn on PFET device 202 in the memory cell 200. The voltage potential at node 246 is then charged to the full high voltage V_{DD} through PFET device 202. The voltage potentials of storage nodes 246 and 245 of the memory cell 200 are then respectively set to V_{DD} and the ground voltage. The datum “1” is written into the memory cell 200.

For writing datum “0” into the memory cell 200 with the voltage V_{DD} to turn on the word-line W (gates of access NFET devices 203 and 204 in 4T-SRAM cell 200) at node 433, the NFET devices 415 and 416 are turned respectively “off” and “on” for the inputted ground voltage signal at node 432. The node 46 for bitline BL 421 are connected through NFET device 412 to the ground voltage, while the node 45 for bitline B̅L̅ 422 with loading capacitance C_{BL} 442 is charged to V_{DD} through PFET device 413 with NFET device 415 off. The ground voltage at node 46 is passed through bitlines BL 421 and the access transistor 204 to turn on PFET device 201 in the memory cell 200. The voltage potential at node 245 is then charged to the full high voltage V_{DD} through PFET 201. The voltage potentials of storage nodes 245 and 246 of the memory cell 200 are then respectively set to V_{DD} and the ground voltage. Therefore, the datum “0” is written into the memory cell 200.

FIG. 5 shows a schematic diagram of a memory device 500 according to another embodiment of the invention. In FIG. 5, a memory device 500 includes the 4T-SRAM cell 200 and a read circuit 510. The read circuit 510 comprises two bitline reset NFET devices 511 for discharging residual charges on the bitline BL 521 with loading capacitance C_{BL} 541 and the complementary bitline B̅L̅ 522 with loading capacitance C_{BL} 542, the send enabled PFET device 512, the two sensing cross-connected inverters 514 and 513, and the tri-state buffer 515. Before reading out the datum stored in 4T-SRAM cell 200, the voltage signal “BLrst” at node 531 is applied with V_{DD} to turn on the NFET devices 511 to discharge any residual charges on the bitline BL 521 and complementary bitline B̅L̅ 522 for a short period of time τ to prevent interfering the voltage potential of the floating storage nodes 245/246 in the selected 4T-SRAM cell 200. For reading out the stored datum “1” in cell 200, the wordline W 433 (gates of access NFET devices 203 and 204 in 4T-SRAM cell 200) is turned on to charge the bitline BL by the PFET device 202 to a high voltage greater than the threshold voltage of the sensing NFET device in the inverter 513 for passing the ground voltage through the complementary bitline B̅L̅ 522 and the access NFET device 203 to the cell node 245. The ground voltage at cell node 245 keeps the PFET device 202 on for sustaining the voltage potential V_{DD} at node 246. A “Snd” signal with voltage potential V_{DD} at node 532 then turns the tri-state buffer 515 on for the input voltage signal V_{SS} at node 55 to send out the cell stored data voltage signal V_{DD} (data “1) to the data out bus-line and meanwhile the PFET device 512 on for accelerating the sensing process to charge the bitline BL 521 to the full high voltage potential V_{DD}. During the read process, the input voltage signal timing sequence for the “BLrst” signal 601, the “Snd” signal 602, the “W” signal 603, the correspondent voltage potential curves 604 and 605 for cell nodes 246 and 245, the bitline signal 606a and 606b, the complementary bitline signal 606a and 606c is shown in FIG. 6. Note that during the read process, the cell node 245 (curve 605 in FIG. 6) is refreshed with the ground voltage from the previous floating storage node in data retention period such that the total charges of PFET device 202 for the capacitance of the ground voltage gate with node 245 and the high voltage V_{DD} biased body have been retained from the previous floating storage node situation.

For reading out the stored data “0” in the cell 200, the wordline 433 (access NFET devices 203 and 204 in 4T-SRAM cell 200) is turned on to charge the complementary bitline B̅L̅ by the PFET device 201 to a high voltage greater than the threshold voltage of the sensing NFET device in the inverter 514 for passing the ground voltage to the bitline BL and the access NFET 504 to the cell node 246. The ground voltage at cell node 246 keeps the PFET 201 on for sustaining the voltage potential V_{DD} at node 245. A “Snd” signal with V_{DD} at node 532 turns the tri-state buffer 515 on for the input voltage signal V_{DD} at node 55 to send out the cell stored data voltage signal Vₛₛ=0 V (data “0”) to the data out bus-line and meanwhile the PFET 512 on for accelerating the sensing process to charge the complementary bitline B̅L̅ to the full high voltage potential V_{DD}. During the read process, the input voltage signal timing sequence for the “BLrst” signal 601, the “Snd” signal 602, the “W” signal 603, the correspondent voltage potential curves 604 and 605 for cell nodes 245 and 246, the bitline signal 607a and 607c, the complementary bitline signal 607a and 607b is shown in FIG. 6. Note that during the read process, the cell node 246 (curve 605 in FIG. 6) is refreshed with the ground voltage from the previous floating storage node in data retention period such that the total charges of PFET 201 for the capacitance of the ground voltage gate with node 246 and the high voltage V_{DD} biased body have been retained from the previous floating storage node situation.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows the schematic of the conventional 6T-SRAM cell 100.

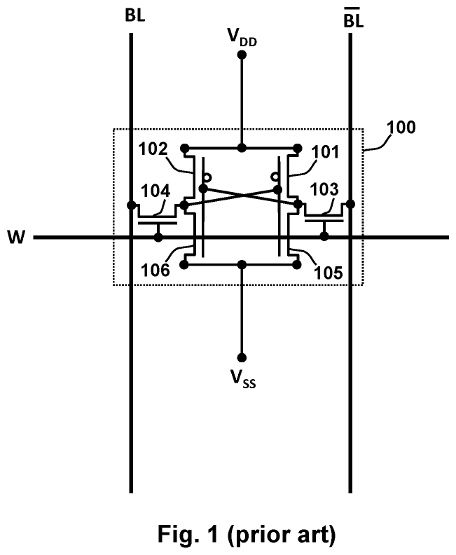

FIG. 2 shows the schematic of a 4T-SRAM cell 200.

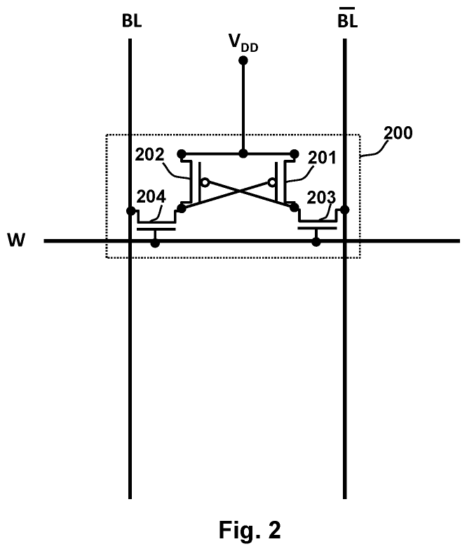

FIGS. 3A and 3B show the schematic of data storage circuits 30L and 30R for 4T-SRAM cell 200 and 6T-SRAM cell 100.

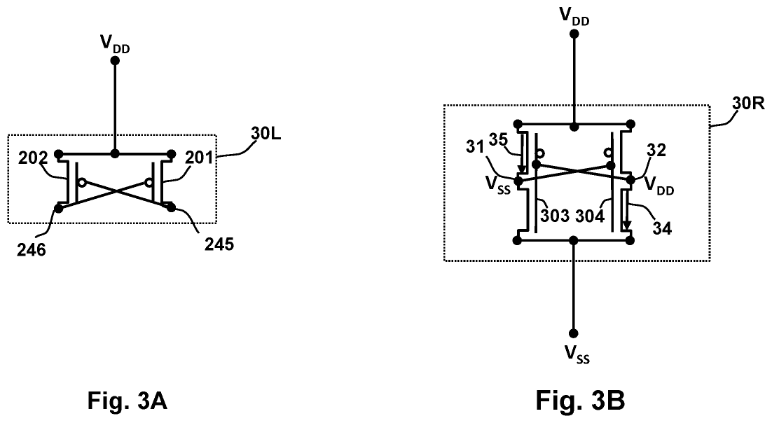

FIG. 4 shows the schematic of a memory device 400 according to an embodiment of the invention.

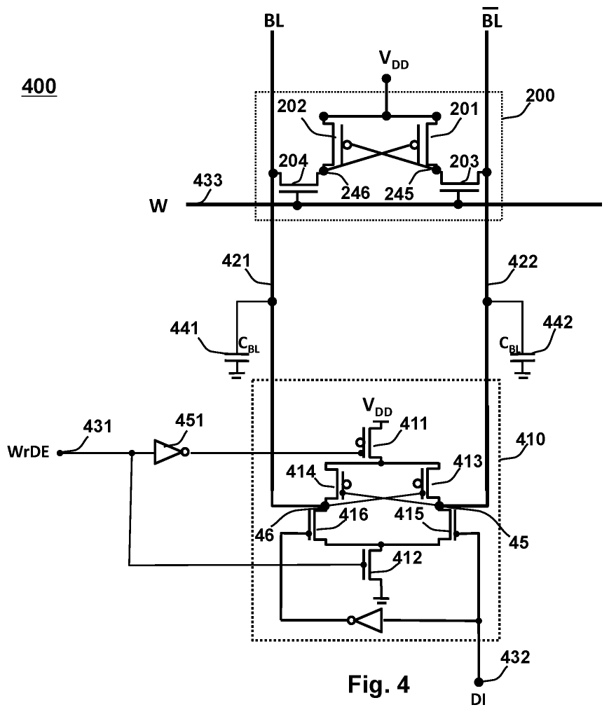

FIG. 5 shows the schematic of a memory device 500 according to another embodiment of the invention in this invention.

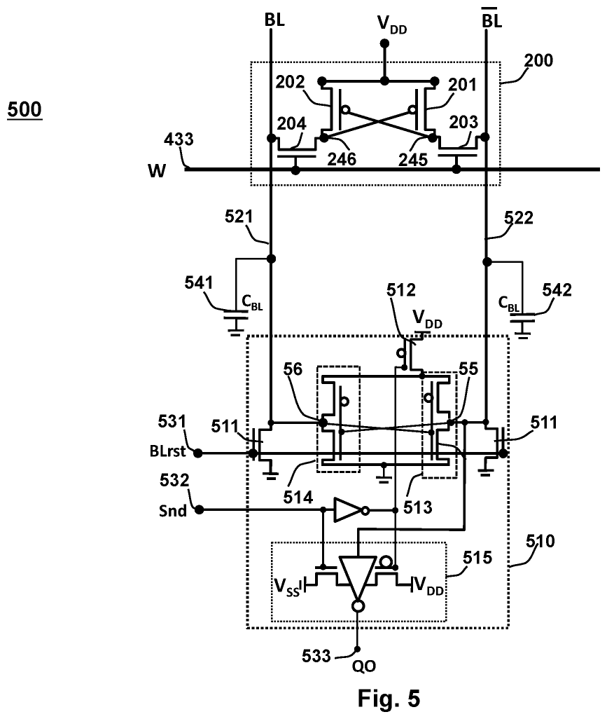

FIG. 6 shows the input voltage timing sequence diagram for the read circuit 510.

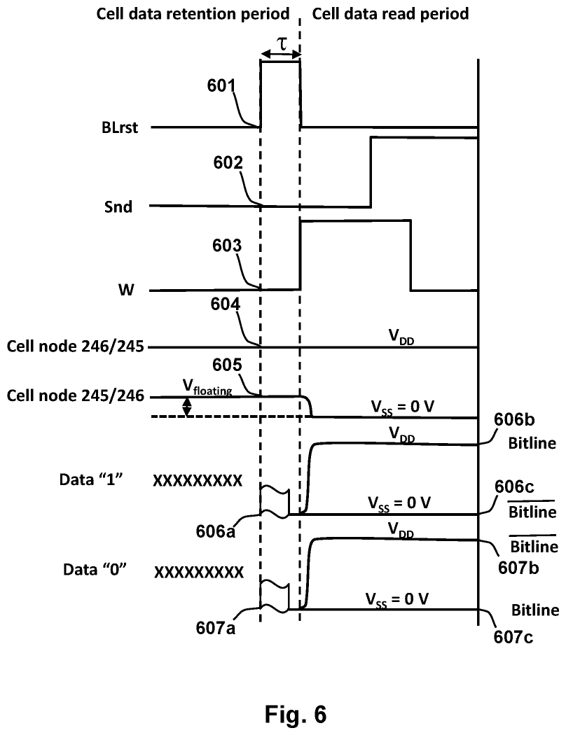

FIG. 7 shows a schematic diagram for an “n×m”-bit 4T-SRAM circuit device 700 in one embodiment of the present invention.

FIG. 8 shows the circuit schematic for an “n×m”-bit 4T-SRAM array 710.

FIG. 9 shows the circuit schematic of a timing control circuit for reading a row of m-bit data from the “n×m”-bit 4T-SRAM memory array 710 and writing a row of m-bit data into the “n×m”-bit 4T-SRAM memory array 710 in the embodiment of the present invention.

FIG. 10 shows a schematic diagram of a sense amplifier 720 for reading out a row of m 4T-SRAM cells in the embodiment of the present invention.

FIG. 11 shows a schematic diagram of a write driver 730 for writing a m-bit word into a row of m 4T-SRAM cells in the embodiment of the present invention.

FIG. 12 shows a timing sequence for reading a m-bit word in a clock cycle according to the clock signal and a read enable signal in the embodiment of the present invention.

FIG. 13 shows a timing sequence for writing a m-bit word in a clock cycle according to the clock signal and write enable signal in the embodiment of the present invention.

### DETAILED DESCRIPTION OF THE INVENTION

The following detailed description is meant to be illustrative only and not limiting. It is to be understood that other embodiment may be utilized and structural changes may be made without departing from the scope of the present invention. Also, it is to be understood that the read circuit and the write circuit used herein are for the purpose of description and should not be regarded as limiting. Those of ordinary skill in the art will immediately realize that the embodiment of the present invention described herein in the context of methods and schematics are illustrative only and are not intended to be in any way limiting. Other embodiment of the present invention will readily suggest themselves to such skilled persons having the benefits of this disclosure.

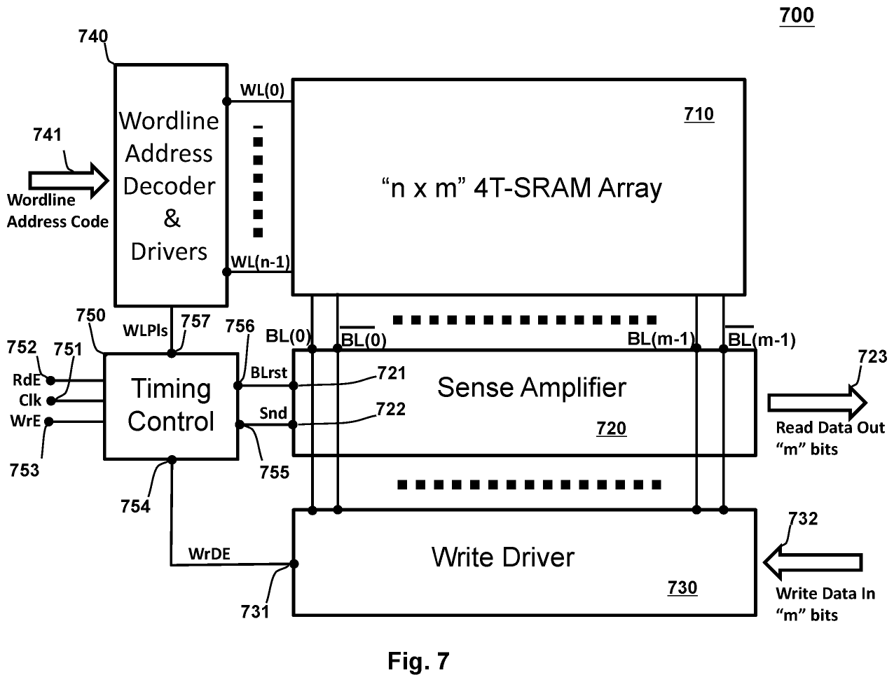

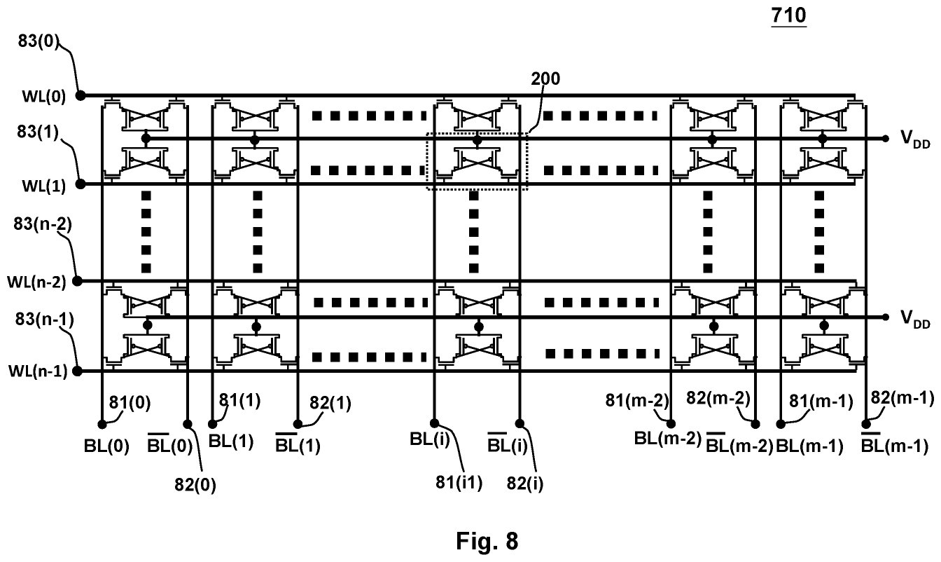

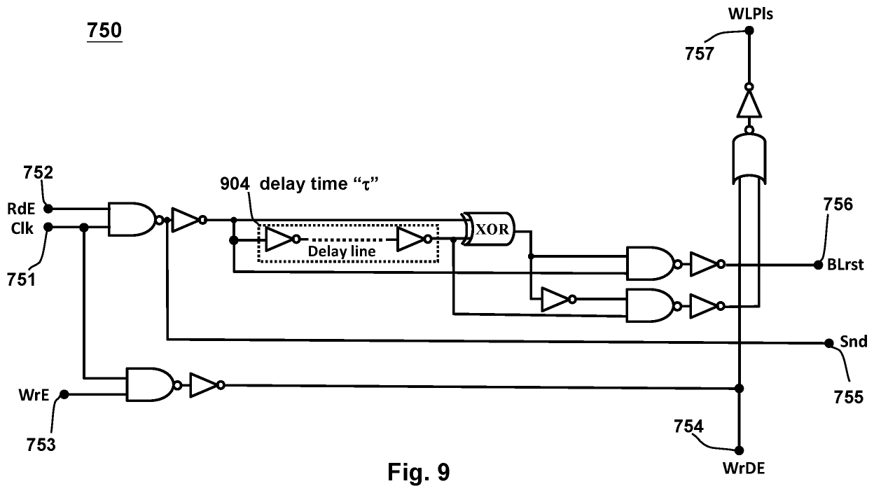

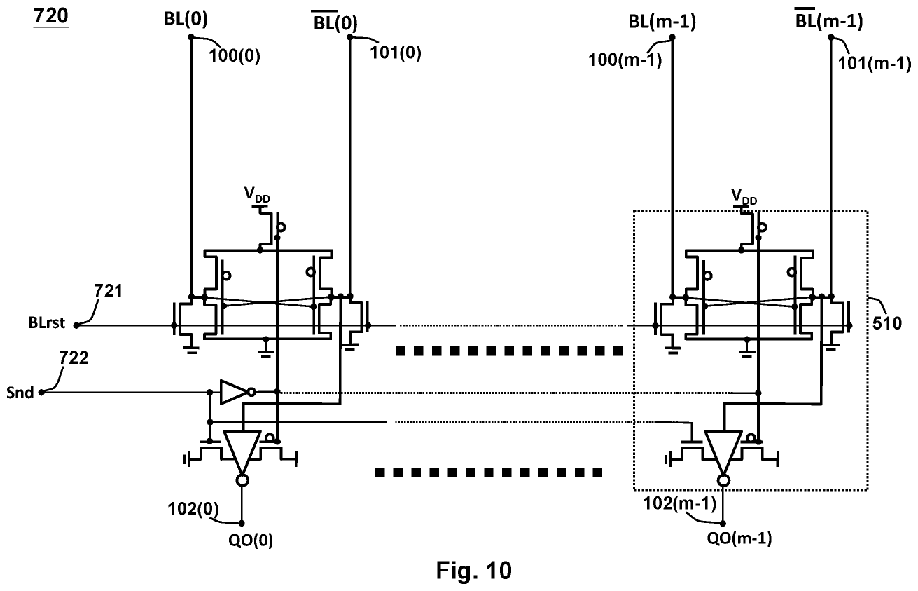

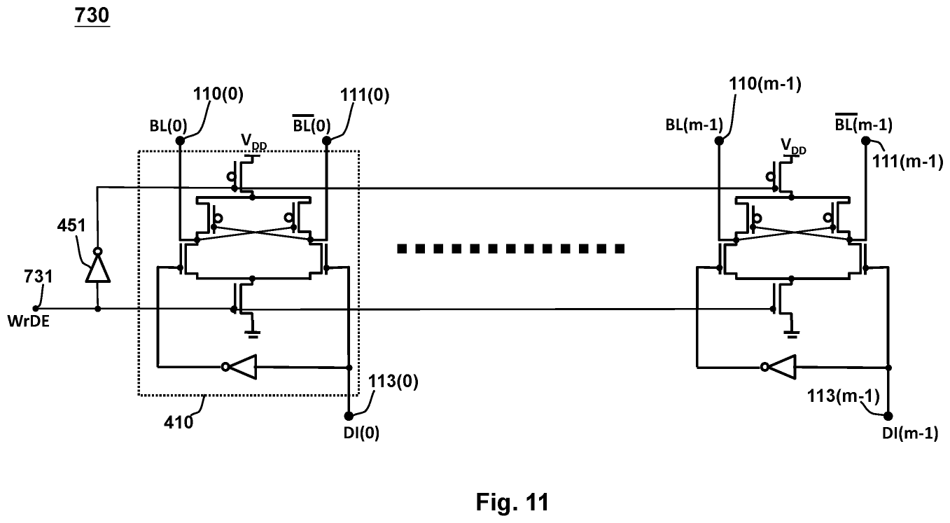

FIG. 7 shows the schematics of a 4T-SRAM circuit device 700. Referring to FIG. 7, the 4T-SRAM circuit device 700 comprises an “n×m”-bit 4T-SRAM array 710 (details in FIG. 8) for “n×m”-bit data storage, a wordline address decoder and driver 740 for decoding the wordline address code from the wordline address inputs 741 to select a wordline in the array 710, a timing control circuit 750 (details in FIG. 9) with a clock signal input node 751, a read-enable signal input node 752, a read wordline pulse signal output node 757, a bitline reset signal output node 756 (721) and a send signal output node 755 (722) in the read sequence, and a write-enable signal input node 753, a write wordline pulse signal output node 757 and a write-driver-enable signal output node 754 (731) in the write sequence, a sense amplifier 720 (details in FIG. 10) for reading out a row of “m” 4T-SRAM cells and sending out the m-bit data voltage signals to the output bus-lines 723, a write driver 730 (details in FIG. 11) with the write-driver-enable signal output node 731 and the m-bit voltage signals input node 732 from the input bus-lines for the data to be written into a row of “m” 4T-SRAM cells 200. Since the structure and operations of the wordline address decoder and driver 740 are well known in the art, its detailed descriptions are omitted herein.

Referring to FIG. 8, the schematic of the “n×m” 4T-SRAM array 710 comprises n-row×m-column 4T-SRAM cells 200. The gates of access transistors 203/204 for each row of 4T-SRAM cells 200 form “n” wordlines WL(0)/83(0), WL(1)/83(1), . . . , WL(n−2)/83(n−2), and WL(n−1)/83(n−1). The source electrodes of each column of access transistors 203/204 form “m” bitlines BL(0)/81(0), BL(1)/81(1), . . . , BL(i)/81(i), . . . , BL(m−2)/81(m−2), BL(m−1)/81(m−1), and “m” complementary bitlines B̅L̅ (0)/82(0), B̅L̅(1)/82(1), . . . , B̅L̅ (i)/82(i), . . . , B̅L̅ (m−2)/82(m−2), and B̅L̅ (m−1)/82(m−1), respectively for the “m” columns of 4T-SRAM cells 200. FIG. 9 shows the timing control circuit 750 with a clock signal “clk” input node 751, a read enable signal “RdE” input node 752, a write enable signal “WrE” input node 753, a bitline reset signal “BLrst” output node 756, a send signal “Snd” output node 755, the write-driver enable-signal “WrDE” output node 754, and the wordline pulse signal “WLPIs” output node 757. FIG. 10 shows the schematic of the sense amplifier 720 for reading out a selected row of “m” 4T-SRAM cells 200. In FIG. 10, the sense amplifier 720 includes m read circuits 510. The bitlines 100(0), . . . , 100(m−1) and complementary bitlines 101(0), . . . , 101(m−1) are connected to the bitlines 81(0), . . . , 81(m−1) and complementary bitlines 82(0), 82(1), . . . , 82(m−1) of the 4T-SRAM array 710 in FIG. 8, respectively. The output nodes QO(0)/102(0), . . . , QO(m−1)/102(m−1) are connected to the data output bus-lines 723. Two input nodes 721 and 722 are connected to the output nodes 756 and 755 of timing control circuit 750 in FIG. 9 for the bitline reset signal “BLrst” and the send signal “Snd”. FIG. 11 shows the schematic of the write driver 730 for writing “m” data voltage signals into a selected row of 4T SRAM cells 200. In FIG. 11, the write driver 730 includes m write circuits 410 and one inverter 451. The bitline nodes 110(0), . . . , 110(m−1) and complementary bitline nodes 111(0), . . . , 111(m−1) are connected to the bitlines 81(0), . . . , 81(m−1) and complementary bitlines 82(0), 82(1), . . . , 82(m−1) of the 4-T SRAM memory array 710 in FIG. 8, respectively. The input nodes 113(0), . . . , 113(m−1) receive the voltage signals DI(0), . . . , DI(m−1) for the data to be written from the data input bus-lines 732. The write driver 730 is activated by the write-driver-enable signal “WrDE” at the input node 731 from the timing control circuit 750 in FIG. 9.

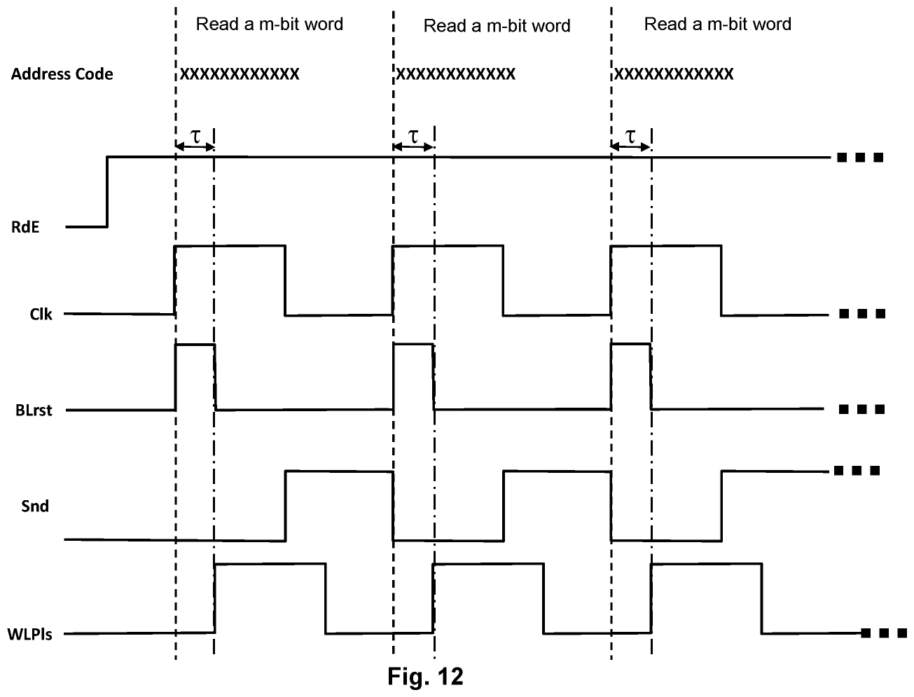

The timing sequence for reading a m-bit word in a clock cycle is shown in FIG. 12. While a wordline address code is sent to the wordline address decoder & drivers 740 for selecting a wordline in the 4T-SRAM array 710, the timing control circuit 750 is activated with the read enable signal “RdE” and the clock signal “clk” at nodes 752 and 751 to generate the output voltage signals “BLrst”, “Snd” and “WLPIs”. The timing delay line 904 in FIG. 9 consisting of an even number “n” of logic gates (inverters) with each logic gate delay Δt generates a delay time τ=(n×Δt) for the duration of bitline discharging as shown in “BLrst” signal in FIG. 12. After discharging any residual charges on both bitlines and complementary bitlines for the time period τ, the selected wordline is then turned on with the “WLPIs” signal of V_{DD} and the “m” read circuits 510 push the stored data voltage signals of the selected row of m-bit memory cells to the data output bus-lines 723 for the time period of the half clock cycle.

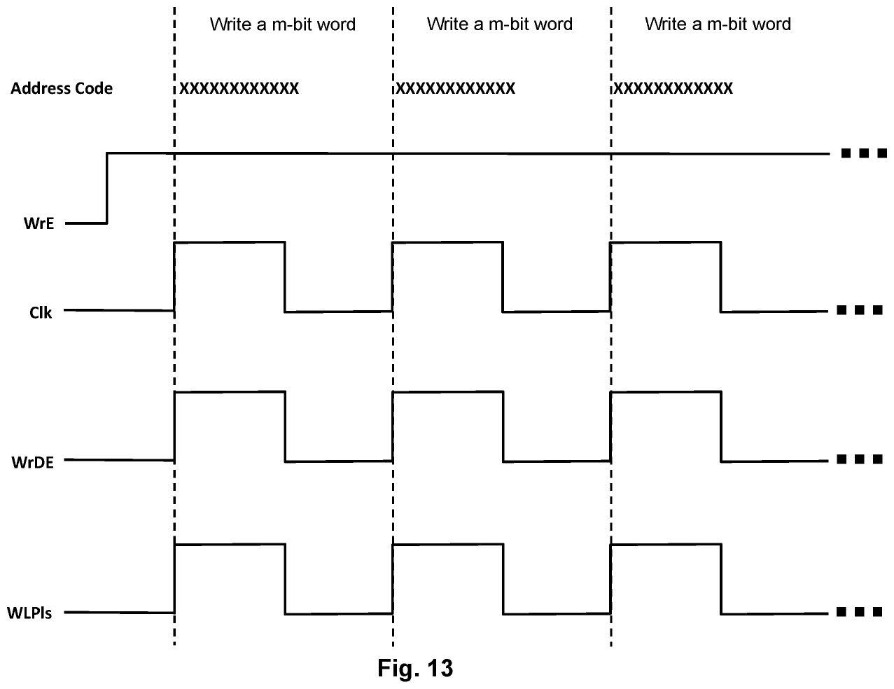

FIG. 13 shows the timing sequence for writing a m-bit word in a clock cycle. When a wordline address code is sent to the wordline address decoder & drivers 740 for selecting a wordline in the 4T-SRAM array 710, the timing control circuit 750 is activated with the write enable signal “WrE” and the clock signal “clk” at nodes 753 and 751 to generate the output voltage signal “WrDE” to turn on the “m” write circuits 410 and the wordline pulse signal “WLPIs” signal for the selected word line.

The aforementioned description of the preferred embodiment of the invention has been presented for purposes of illustration and description. It is not intended to be exhaustive or to limit the invention to the precise form or to exemplary embodiment disclosed. Accordingly, the description should be regarded as illustrative rather than restrictive. The embodiment is chosen and described in order to best explain the principles of the invention and its best mode practical application, thereby to enable persons skilled in the art to understand the invention for various embodiment and with various modifications as are suited to the particular use or implementation contemplated. It is intended that the scope of the invention be defined by the claims appended hereto and their equivalents in which all terms are meant in their broadest reasonable sense unless otherwise indicated. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiment of the invention. It should be appreciated that variations may be made in the embodiment described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A memory device, comprising:
a SRAM cell comprising:
a cross-coupled pair of PMOS transistors coupled to a supply voltage rail and two storage nodes; and
two access transistors responsive to a word line and coupled to the two storage nodes and a bit line pair; and
a write circuit comprising:
a cross-coupled pair of pull-up transistors coupled between the supply voltage rail and the bit line pair; and
two setting transistors responsive to a data line pair and coupled to a ground voltage rail, the bit line pair and the cross-coupled pair of pull-up transistors.

2. The memory device according to claim 1, wherein the write circuit further comprises:
a switching device responsive to a control line pair and coupled to the supply voltage rail, the ground voltage rail, the cross-coupled pair of pull-up transistors and the two setting transistors.

3. The memory device according to claim 2, wherein the switching device comprises:
a PMOS transistor responsive to one of the control line pair and coupled between the supply voltage rail and the cross-coupled pair of pull-up transistors; and
a NMOS transistor responsive to the other control line of the control line pair and coupled between the ground voltage rail and the two setting transistors.

4. The memory device according to claim 1, wherein the two access transistors comprise a first access transistor and a second access transistor responsive to the word line, wherein the first access transistor is coupled between one of the two storage nodes and one of the bit line pair, and wherein the second access transistor is coupled between the other storage node of the two storage nodes and the other bit line of the bit line pair.

5. The memory device according to claim 1, wherein the two setting transistors comprise a first setting transistor and a second setting transistor, wherein the first setting transistor is coupled to one of the bit line pair, one of the cross-coupled pair of pull-up transistors and the ground voltage rail and responsive to one of the data line pair, wherein the second setting transistor is coupled to the other bit line of the bit line pair, the other transistor of the cross-coupled pair of pull-up transistors and the ground voltage node and responsive to the other data line of the data line pair.

6. A method of writing a data bit into a SRAM cell in a memory device comprising a write circuit, wherein the SRAM cell comprises a cross-coupled pair of PMOS transistors and two access transistors, the cross-coupled pair of PMOS transistors being coupled to a supply voltage rail and two storage nodes, the two access transistors being responsive to a word line and coupled to the two storage nodes and a bit line pair, wherein the write circuit comprises a cross-coupled pair of pull-up transistors and two setting transistors, and the cross-coupled pair of pull-up transistors is coupled between the supply voltage rail and the bit line pair, wherein the two setting transistors are responsive to a data line pair and coupled to a ground voltage rail, the bit line pair and the cross-coupled pair of pull-up transistors, the method comprising the steps of:
(1) turning on the two access transistors to respectively connect the two storage nodes to the bit line pair by activating the word line;
(2) turning on one of the two setting transistors and turning off the other setting transistor of the two setting transistors by inputting the data bit through the data line pair so as to discharge one of the bit line pair to a ground voltage and charge the other bit line to a supply voltage;
(3) causing one of the two storage nodes coupling to the discharged bit line to have the ground voltage through one of the turned-on two access transistors after the steps of (1) and (2); and
(4) causing one of the cross-coupled pair of PMOS transistors to be turned on to charge the other storage node of the two storage nodes to the supply voltage after the step of (3).

7. The method according to claim 6, further comprising:
turning on a PMOS transistor and a NMOS transistor by activating a control line pair to connect the supply voltage rail and the cross-coupled pair of pull-up transistors and to connect the ground voltage rail and the two setting transistors prior to the step of (2);
wherein the write circuit further comprises:
the PMOS transistor responsive to one of the control line pair and coupled between the supply voltage rail and the cross-coupled pair of pull-up transistors; and
the NMOS transistor responsive to the other control line of the control line pair and coupled between the ground voltage rail and the two setting transistors.

8. A memory device, comprising:
a SRAM cell comprising:
a cross-coupled pair of PMOS transistors coupled to a supply voltage rail and two storage nodes; and
two access transistors responsive to a word line and coupled to the two storage nodes and a bit line pair; and
a read circuit comprising:
a latch coupled between the supply voltage rail and a ground voltage rail and having two output nodes that are coupled to the bit line pair respectively; and
a discharge device responsive to a first control line for a predefined duration and coupled to the two output nodes, the bit line pair and the ground voltage rail.

9. The memory device according to claim 8, wherein the discharge device comprises:
a first reset transistor and a second reset transistor responsive to the first control line for the predefined duration, wherein the first reset transistor is coupled to one of the two output nodes, one of the bit line pair and the ground voltage rail, and wherein the second reset transistor is coupled to the other output node of the two output nodes, the other bit line of the bit line pair and the ground voltage rail.

10. The memory device according to claim 8, wherein the read circuit further comprises:
a tri-state buffer responsive to a second control line and having a data input node coupled to one of the two output nodes.

11. The memory device according to claim 8, wherein the read circuit further comprises:
an accelerating transistor responsive to a second control line and coupled between the supply voltage rail and the latch.

12. The memory device according to claim 8, wherein upon activation of the word line, voltages of the two storage nodes are detected by the read circuit to be respectively a supply voltage and a floating voltage, wherein the floating voltage is greater than a ground voltage and less than the supply voltage, and wherein the floating voltage is obtained by detailed balanced leakage currents between a channel diffusion current with a reversed P-drain/N-well junction leakage current for one of the cross-coupled pair of PMOS transistors and a reversed N-drain/P-substrate junction leakage current for one of the two access transistors in connection with one of the two storage nodes having the floating voltage.

13. The memory device according to claim 12, wherein after the activation of the word line, one of the two storage nodes originally having the floating voltage is refreshed to the ground voltage.

14. A method of reading a data bit from a SRAM cell in a memory device comprising a read circuit, wherein the SRAM cell comprises a cross-coupled pair of PMOS transistors and two access transistors, the cross-coupled pair of PMOS transistors being coupled to a supply voltage rail and two storage nodes, the two access transistors being responsive to a word line and coupled to the two storage nodes and a bit line pair, wherein the read circuit comprises a latch and a discharge device, the latch being coupled between the supply voltage rail and a ground voltage rail and having two output nodes that are coupled to the bit line pair respectively, wherein the discharge device is coupled to the two output nodes, the bit line pair and the ground voltage rail and responsive to a first control line, the method comprising the steps of:
(1) discharging the bit line pair to a ground voltage through the discharge device by activating the first control line for a predefined duration;
(2) charging a first bit line of the bit line pair to a supply voltage through one of the cross-coupled pair of PMOS transistors and one of the two access transistors by activating the word line so that a first output node of the two output nodes connected to the first bit line is charged to the supply voltage after the step of (1);
(3) causing a second output node of the two output nodes to have the ground voltage through the latch after the step of (2);
(4) causing a first storage node of the two storage nodes to have the ground voltage through a second bit line of the bit line pair connected to the second output node and the first storage node after the step of (3); and
(5) causing a second storage node of the two storage nodes to sustain the supply voltage through the one of the cross-coupled pair of PMOS transistors after the step of (4).

15. The method according to claim 14, further comprising:
outputting the data bit through a tri-buffer by activating a second control line after the step of (5);
wherein the read circuit further comprises the tri-state buffer responsive to the second control line and having a data input node coupled to one of the two output nodes.

16. The method according to claim 14, further comprising:
coupling the supply voltage rail and the latch through an accelerating transistor by activating a second control line to accelerate to charge the first bit line to the supply voltage prior to the step of (2);
wherein the accelerating transistor is responsive to the second control line and coupled to the supply voltage rail and the latch.

17. The method according to claim 14, wherein the step of (2) further comprises:
upon activation of the word line, detecting the two storage nodes by the read circuit to obtain voltages of the two storage nodes being the supply voltage and a floating voltage, wherein the floating voltage is greater than the ground voltage and less than the supply voltage, and wherein the floating voltage is obtained by detailed balanced leakage currents between a channel diffusion current with a reversed P-drain/N-well junction leakage current for one of the cross-coupled pair of PMOS transistors and a reversed N-drain/P-substrate junction leakage current for one of the two access transistors in connection with the first storage node having the floating voltage.
